(19) United States
(12) Patent Application Publication
(10) Pub. No.: US 2023/0280644 A1
(43) Pub. Date: Sep. 7, 2023

(54) METHOD OF MAKING EUV MASK WITH AN ABSORBER LAYER

(71) Applicant: INTERNATIONAL BUSINESS MACHINES CORPORATION, ARMONK, NY (US)

(72) Inventors: Dario Goldfarb, Dobbs Ferry, NY (US); Martin Burkhardt, White Plains, NY (US); Romain Lallement, Troy, NY (US); Luciana Meli, Albany, NY (US)

(21) Appl. No.: 17/653,296

(22) Filed: Mar. 3, 2022

(51) Int. Cl. G03F 1/24

(52) U.S. Cl. CPC G03F 1/24

(57) ABSTRACT

Embodiments of present invention provide a method of forming an extreme ultraviolet (EUV) mask. The method includes subliming a radiation-sensitive material onto a surface of an EUV blank substrate; exposing the radiation-sensitive material to an ionizing radiation to form an EUV mask pattern; and removing a portion of the radiation-sensitive material from the surface of the EUV blank substrate where the portion of the radiation-sensitive material is unexposed to the ionizing radiation. An EUV mask made therefrom, and the related radiation-sensitive material are also provided.

### FIELD OF THE INVENTION

The present application relates to manufacturing of semiconductor integrated circuits. More particularly, it relates to masks used in extreme ultraviolet (EUV) lithography, making of the masks, and materials used in making the masks.

### BACKGROUND

As the dimension of integrated circuit devices shrinks, a variety of single-patterning or double-patterning lithographic processes such as, for example, those that are based on deep ultraviolet (DUV) radiation wavelengths at 193 nanometers (nm) have come into widespread use. Recent development of extreme ultraviolet (EUV) lithographic processes based on radiation wavelengths at 13.5 nm, for example, is expected to facilitate and further improve the accurate patterning of semiconductor device features at sub-10 nm production nodes.

EUV lithography uses specialized EUV masks that usually include a mask absorber or absorber layer. In high numerical aperture (NA) EUV lithography, the mask absorber layer is required to be ultrathin in order to account for and avoid shadowing effect. There are some metal elements that are suitable for making thin metal absorbers. However, it is known to be difficult to etch these metal elements due to their difficulty in generating volatile metallic byproducts. In order to make thin metal absorbers from these metal elements, physical etching processes such as sputtering technique are generally required which complicates the overall manufacturing process and increases the cost associated with the manufacturing.

### SUMMARY

What is needed, as recognized by inventors of this application, is creating, forming, and/or finding novel materials, and method associated with processing these materials, to create metallic nanostructures that may be used as mask absorber. Embodiments of present invention use ionizing beam such as electron beam (e-beam) lithography in processing these novel materials to create mask absorbers that are formed directly on top of an EUV blank substrate, thereby avoiding the usual transferring of printed resist pattern or image onto EUV blank substrate.

Embodiments of present invention provide a method of forming an extreme ultraviolet (EUV) mask. The method includes subliming a layer of radiation-sensitive material onto a surface of an EUV blank substrate; exposing the layer of radiation-sensitive material to an ionizing radiation to form an EUV mask pattern; and removing a portion of the layer of radiation-sensitive material from the surface of the EUV blank substrate, wherein the portion of the layer of radiation-sensitive material is unexposed to the ionizing radiation. In one aspect, the EUV blank substrate includes an EUV reflector multilayer formed on top of an EUV mask substrate. One embodiment further includes densifying the portion of the radiation-sensitive material that is exposed to the ionizing radiation.

According to one embodiment, the radiation-sensitive material includes one or more EUV absorbing chemical compounds of nickel acetate, nickel formate, nickel acetylacetonate, polynuclear nickel complexes, platinum and palladium complexes with azide, carbonate, oxalate and acetylacetonate, polynuclear palladium and platinum complexes, silver and gold complexes with unsaturated hydrocarbons and phosphines, polynuclear silver and gold complexes, chromium complexes with arenes, thiocyanates and bipyridines, and polynuclear chromium complexes.

In one embodiment, the radiation-sensitive material includes organic ligands and exposing the radiation-sensitive material to the ionizing radiation includes removing the organic ligands from a portion of the radiation-sensitive material that is exposed to the ionizing radiation. In another embodiment, the radiation-sensitive material includes one or more EUV absorbing metallic elements of silver (Ag), platinum (Pt), palladium (Pd), gold (Au), nickel (Ni), and chromium (Cr).

In one embodiment, removing the portion of the layer of radiation-sensitive material includes subliming the portion of the layer of radiation-sensitive material to lift from the EUV blank substrate.

Embodiments of present invention also provide an extreme ultraviolet (EUV) mask blank. The EUV mask blank includes an EUV mask substrate; an EUV reflector multilayer on top of the EUV mask substrate; and an imaging layer on top of the EUV reflector multilayer, wherein the imaging layer is a layer of radiation-sensitive material including one or more EUV absorbing metallic elements such as silver (Ag), platinum (Pt), palladium (Pd), gold (Au), nickel (Ni), and chromium (Cr), and is radiation-patternable.

In one embodiment, the imaging layer of the EUV mask blank includes one or more organic ligands that are selected from a group that includes acetate, formate, acetylacetonate, azide, carbonate, oxalate, unsaturated hydrocarbons, phosphines, arenes, thiocyanates and bipyridines.

In another embodiment, the imaging layer of the EUV mask blank includes one or more EUV absorbing chemical compounds of nickel acetate; nickel formate; nickel acetylacetonate; polynuclear nickel complexes, platinum and palladium complexes with azide, carbonate, oxalate and acetylacetonate; polynuclear palladium and platinum complexes, silver and gold complexes with unsaturated hydrocarbons and phosphines; polynuclear silver and gold complexes, chromium complexes with arenes, thiocyanates and bipyridines; and polynuclear chromium complexes with arenes, thiocyanates and bipyridines.

In one embodiment, the EUV reflector multilayer of the EUV mask blank includes multiple transition metal molybdenum (Mo) layers and multiple silicon (Si) layers alternatingly stacked together one over another.

In another embodiment, the EUV mask substrate of the EUV mask blank includes a low thermal expansion material of fused silica, quartz, or silicon carbide.

Embodiments of present invention further provide a radiation-patternable material. The material includes one or more extreme ultraviolet (EUV) absorbing metallic elements; and organic ligands selected from a group that includes acetate, formate, acetylacetonate, azide, carbonate, oxalate, unsaturated hydrocarbons, phosphines, arenes, thiocyanates and bipyridines, wherein the radiation-patternable material is adapted for deposition, through a sublimation process, on a surface of an EUV blank substrate to form an ultrathin film.

In one embodiment, the one or more EUV absorbing metallic elements include one or more of silver (Ag), platinum (Pt), palladium (Pd), gold (Au), nickel (Ni), and chromium (Cr).

In another embodiment, the radiation-patternable material includes one or more EUV absorbing chemical compounds of nickel acetate; nickel formate; nickel acetylacetonate; polynuclear nickel complexes, platinum and palladium complexes with azide, carbonate, oxalate and acetylacetonate; polynuclear palladium and platinum complexes, silver and gold complexes with unsaturated hydrocarbons and phosphines; polynuclear silver and gold complexes, chromium complexes with arenes, thiocyanates and bipyridines; and polynuclear chromium complexes with arenes, thiocyanates and bipyridines.

In yet another embodiment, the radiation-sensitive material includes organic ligands selected from a group that includes acetate, formate, acetylacetonate, azide, carbonate, oxalate, unsaturated hydrocarbons, phosphines, arenes, thiocyanates and bipyridines.

### BRIEF DESCRIPTION OF THE DRAWINGS

The present invention will be understood and appreciated more fully from the following detailed description of embodiments of the invention, taken in conjunction with accompanying drawings of which:

FIGS. 1-7 are demonstrative illustration of cross-sectional views of an EUV mask during a process of manufacturing thereof according to embodiments of present invention, and

FIG. 8 is a demonstrative illustration of a flow-chart of a method of manufacturing an EUV mask according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity or they are embodied in a single physical entity.

### DETAILED DESCRIPTION OF PREFERRED EMBODIMENTS

Illustrative embodiments are described herein in the context of EUV lithography processes, associated EUV masks and mask material stacks, and materials used in the making of EUV masks. However, it is to be understood that embodiments of present invention are not limited to these illustrative masks but are instead more broadly applicable to a wide variety of different mask stacks, and their patterning techniques. These and numerous other variations in the disclosed arrangements will be apparent to those skilled in the art.

Illustrative embodiments involve forming a mask absorber layer on top of an EUV mask blank. The mask absorber layer may be formed by deposition techniques including, but are not limited to, sublimation, plasma enhanced chemical vapor deposition (PECVD), low pressure chemical vapor deposition (LPCVD), physical vapor deposition (PVD), and spin coating. It should also be noted that references herein to formation of one layer or structure “on” or “on top of” or “over” another layer or structure are intended to be broadly construed and should not be interpreted as precluding the presence of one or more intervening layers or structures.

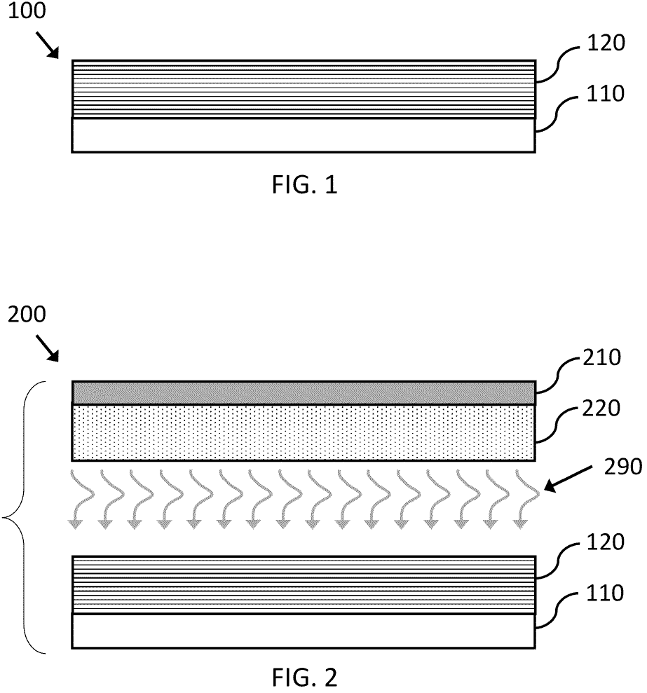

FIGS. 1 through 7 demonstratively illustrate a process of forming an EUV mask in accordance with one or more embodiments of present invention. The figures illustrate respective cross-sectional views of a portion of the EUV mask as it undergoes sequential processing operations as part of the manufacturing process. It is to be appreciated that the various elements and other features shown in these figures are simplified for clarity and for simplicity of illustration and are not necessarily drawn to scale.

FIG. 1. is a demonstrative illustration of a cross-sectional view of an EUV mask in the process of manufacturing thereof in accordance with one embodiment of present invention. More specifically, FIG. 1 illustrates an EUV blank substrate 100 that includes an EUV mask substrate 110 and an EUV reflector multilayer 120 on top thereof. EUV mask substrate 110 may be a substrate made of a low thermal expansion (LTE) material such as, for example, fused silica, quartz, silicon carbide, or other low thermal expansion substances known in the art. The LTE material might be doped with low amounts of inorganic compounds such as, for example, transition metal oxides to enhance the LTE properties of EUV mask substrate 110.

EUV reflector multilayer 120 may have a multilayer structure and may be made of, for example, transition metal molybdenum (Mo) layers and silicon (Si) layers alternatingly stacked together one over another. In other words, EUV reflector multilayer 120 may be made of multiple Mo layers and multiple Si layers stacked together in an alternating fashion. EUV reflector multilayer 120 may be formed on top of EUV mask substrate 110 through, for example, multiple deposition processes to achieve a total combined thickness from about 200 nm to about 500 nm. EUV reflector multilayer 120 may work as a Bragg reflector that enhances and/or maximizes reflection of the 13.5 nm wavelength radiation used in EUV lithography.

FIG. 2. is a demonstrative illustration of a cross-sectional view of an EUV mask in the process of manufacturing thereof in accordance with one embodiment of present invention. More specifically, according to one embodiment, FIG. 2 demonstratively illustrates a step in a process of forming a layer of radiation-sensitive material (310 in FIG. 4) on top of EUV blank substrate 100 or, more specifically, on top of EUV reflector multilayer 120 over EUV mask substrate 110. Details of the radiation-sensitive material layer, referred to herein as an RSM layer, such as its material properties may be described below in more details with reference to FIG. 4.

More particularly, FIG. 2 illustrates an arrangement 200 wherein a target material layer 220 may be attached to a holding substrate 210. Target material layer 220 may be a same radiation-sensitive material (RSM) layer as that of RSM layer 310 and may be used to form RSM layer 310. During the formation of RSM layer 310, target material layer 220, together with its holding substrate 210, may be placed directly above EUV reflector multilayer 120 of EUV blank substrate 100.

The radiation-sensitive material of target material layer 220 may be deposited onto EUV reflector multilayer 120 on top of EUV mask substrate 110 through a sublimation process. More specifically, embodiments of present invention provide a method of subliming target material layer 220 of radiation-sensitive material directly from solid state into vapor state by heating holding substrate 210. For example, target material layer 220 may be heated through, for example, heating holding substrate 210 to a temperature ranging between 90 and 400° C., thereby creating a vapor state 290 of the radiation-sensitive material. The vapor state 290 of radiation-sensitive material may subsequently be used to form RSM layer 310 as being described below in more details.

Target material layer 220 may include one or more EUV absorbing metallic elements such as, for example, silver (Ag), platinum (Pt), palladium (Pd), gold (Au), nickel (Ni), and/or chromium (Cr). Target material layer 220 may also include one or more organic ligands that may be from a group that includes acetate, formate, acetylacetonate, azide, carbonate, oxalate, unsaturated hydrocarbons, phosphines, arenes, thiocyanates and bipyridines. More generally, target material layer 220 may include one or more EUV absorbing chemical compounds that are made of one or more EUV absorbing metallic elements of Ag, Pt, Pd, Au, Ni, and Cr, in combination with, in a singular or polynuclear complex form, one or more organic ligands such as those listed above.

To further illustrate the above, as a non-limiting and non-exhaustive list, the EUV absorbing chemical compounds may include, for example, nickel acetate; nickel formate; nickel acetylacetonate; polynuclear nickel complexes, platinum and palladium complexes with azide, carbonate, oxalate and acetylacetonate; polynuclear palladium and platinum complexes, silver and gold complexes with unsaturated hydrocarbons and phosphines; polynuclear silver and gold complexes, chromium complexes with arenes, thiocyanates and bipyridines; and polynuclear chromium complexes with arenes, thiocyanates and bipyridines. However, embodiments of present invention are not limited in this aspect. A person skilled in the art will appreciate that EUV absorbing chemical compounds with other combinations of one or more EUV absorbing metallic elements, in their singular or polynuclear form, together with one or more organic ligands are possible and fully contemplated here as well.

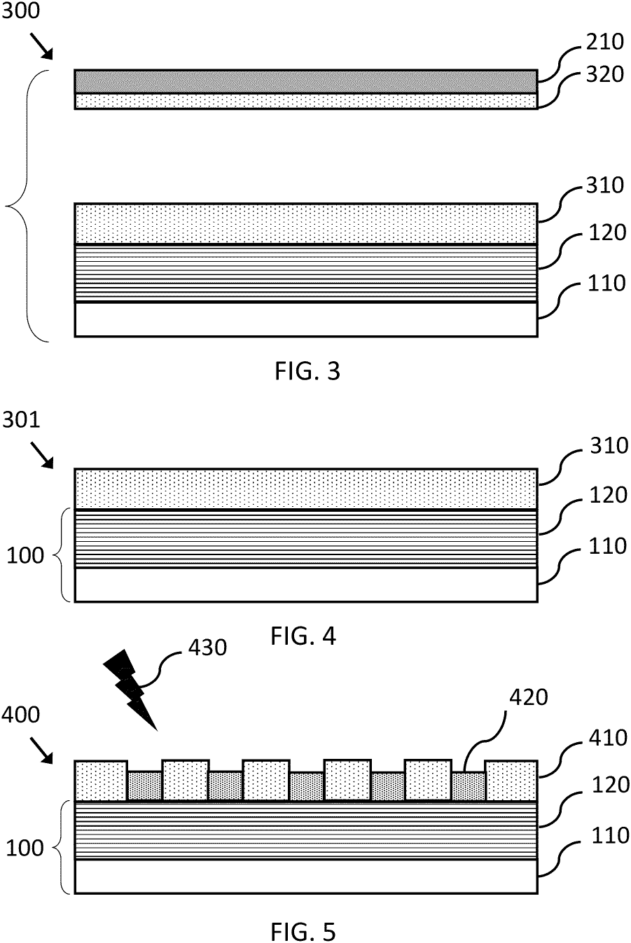

FIG. 3 is a demonstrative illustration of a cross-sectional view of an EUV mask in the process of manufacturing thereof in accordance with one embodiment of present invention. More specifically, FIG. 3 demonstratively illustrates another step in the process of forming RSM layer 310.

More particularly, FIG. 3 illustrates an arrangement 300 wherein a portion of target material layer 220 has been deposited onto EUV reflector multilayer 120 as RSM layer 310 while rest of the target material layer 220 remains on holding substrate 210 as a residual target material layer 320. More specifically, embodiments of present invention provide a method of turning vapor state 290 of the radiation-sensitive material of target material layer 220 into solid state by subjecting vapor state 290 of the radiation-sensitive material to a cooling process, thereby causing deposition of the radiation-sensitive material on top of EUV reflector multilayer 120 over EUV mask substrate 110. For example, in accordance with one embodiment of present invention, vapor state 290 of the radiation-sensitive material may be placed near a relatively cool surface of EUV reflector multilayer 120, while the relatively cool surface of EUV reflector multilayer 120 may be achieved by cooling EUV blank substrate 100. According to one embodiment, the surface of EUV reflector multilayer 120 may be cooled down to a temperature ranging from about 10 to about 90° C., for a duration or period of about 1 to 100 minutes.

FIG. 4 is an alternative illustration of arrangement 300 in FIG. 3 without showing the residual target material layer 320 with its holding substrate 210. More specifically, FIG. 4 demonstratively illustrates an EUV mask blank 301 wherein RSM layer 310 is deposited on top of EUV blank substrate 100, i.e., on top of EUV reflector multilayer 120 over EUV mask substrate 110. The RSM layer 310 may have a thickness ranging from about 50 nm to about 500 nm, and more preferably from about 100 nm to about 200 nm. According to embodiments of present invention, RSM layer 310 may be lithographic patterned later to form an EUV absorber or absorber layer, and for that reason may be referred to hereinafter as an imaging layer. Additionally, because of its radiation-sensitive material, RSM layer 310 may be a radiation-patternable imaging layer.

Here, a person skilled in the art will appreciate that embodiments of present invention of forming RSM layer 310, i.e., a radiation-patternable imaging layer, on top of EUV blank substrate 100 are not limited to the above aspects. Various currently known or future developed methods and/or processes may be applied to form RSM layer 310. For example, processes such as plasma-enhanced chemical vapor deposition (PECVD), low-pressure chemical vapor deposition (LPCVD), physical vapor deposition (PVD) as well as spin-coating processes may be used to apply or form RSM layer 310 on top of EUV blank substrate 100.

As being discussed above, RSM layer 310 is a layer of radiation-sensitive material. In other words, material properties of RSM layer 310 may cause RSM layer 310 to react to certain ionizing radiation exposure, such as electron beam (e-beam) and be processed to become a patterned absorber layer. In other words, RSM layer 310 may be patternable through exposing to ionizing radiation and thus may be referred to as radiation-patternable layer.

FIG. 5 is a demonstrative illustration of a cross-sectional view of an EUV mask in the process of manufacturing thereof in accordance with one embodiment of present invention. More specifically, one embodiment includes subjecting RSM layer 310 to an ionizing radiation such as an electron beam (e-beam) exposure 430 to create a mask pattern 420. In other words, a portion or portions of RSM layer 310 may be exposed to ionizing radiation, causing changes in material properties of RSM layer 310. For example, organic ligands inside the portions of RSM layer 310 that have been exposed, may be removed. The process of removing organic ligands may take place in a vacuum environment of a radiation exposure chamber. Being non-ionic and having low molecular mass, the organic ligands are volatilized and pumped out of the radiation exposure chamber. In some cases, the sensitivity of RSM layer 310 to radiation may correlate with the ligand molecular mass, in which case the ligand modulates the RSM decomposition kinetics.

Subsequent to the radiation exposure 430, the exposed portion of RSM layer 310, that is, mask pattern 420 illustrated in FIG. 5 may be subjected to a densification process. In one embodiment, some densification process may have already occurred naturally during the exposure process as well, as a result of the mass loss and volatilization of the organic ligands. According to one embodiment, the densification process may be thermally enhanced during a subsequent development process, after the completion of the patten-wise exposure step that creates mask pattern 420. The densified mask pattern 420 may subsequently be formed into an EUV absorber or absorber layer 510 (see FIG. 7).

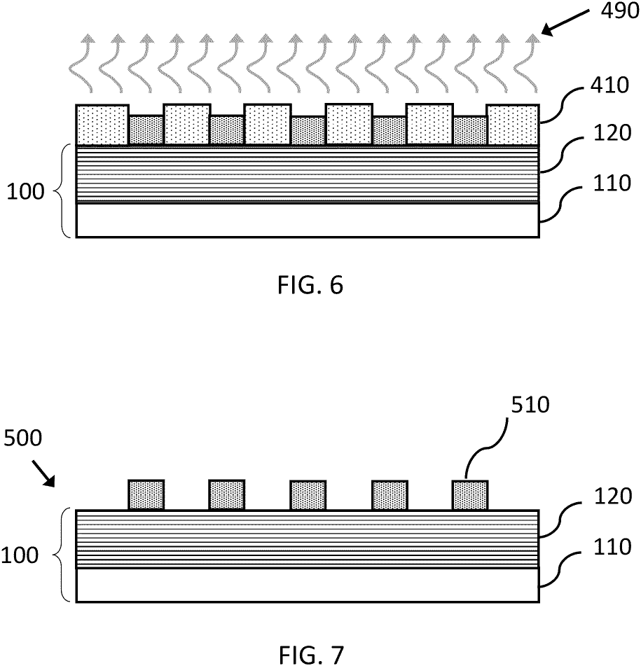

FIG. 6 is a demonstrative illustration of a cross-sectional view of an EUV mask in the process of manufacturing thereof in accordance with one embodiment of present invention. More specifically, following the radiation exposure and densification process, embodiments of present invention include applying a development process to remove an un-exposed portion of RSM layer 310, that is, remaining RSM layer 410 as illustrated in FIG. 5. In one embodiment, the development process may be a dry development process by sublimating the un-exposed portion of RSM layer 310 off the EUV mask blank 301. In other words, remaining RSM layer 410 of the un-exposed portion of RSM layer 310 may be removed through sublimating from a top surface of EUV blank substrate 100. For example, structure 400 may be subjected to a heated environment. The heated environment may be a stand-alone heat chamber, or a load-lock of the radiation exposure system adapted for substrate heating. The dry development process can be conducted at a temperature around, for example, 200° C., to cause remaining RSM layer 410 turning into vapor state 490 directly.

In another embodiment, the development process may be a wet development process consisting of dispensing a liquid developer that dissolves the unexposed portions of RSM layer 310. The liquid developer may be a light organic solvent selected from a group that includes, for example, alcohols, esters, ketones, and hydrocarbons. Examples of liquid developers are isopropanol, acetone, butyl acetate, and hexane.

FIG. 7 is a demonstrative illustration of a cross-sectional view of an EUV mask in the process of manufacturing thereof in accordance with one embodiment of present invention. More specifically, FIG. 7 demonstratively illustrates a structure which is an EUV mask 500 with a patterned EUV absorber or absorber layer 510 on top of EUV blank substrate 100 including EUV reflector multilayer 120 and EUV mask substrate 110. The patterned EUV absorber or absorber layer 510 may include one or more EUV absorbing metallic elements such as, for example, Ag, Pt, Pd, Au, Ni, and Cr. In addition, the patterned EUV absorber or absorber layer 510 may possibly include trace amounts of organic chemical compounds such as C, H, O, N, P and/or S, as a result of an incomplete removal of all non-metallic chemical compounds.

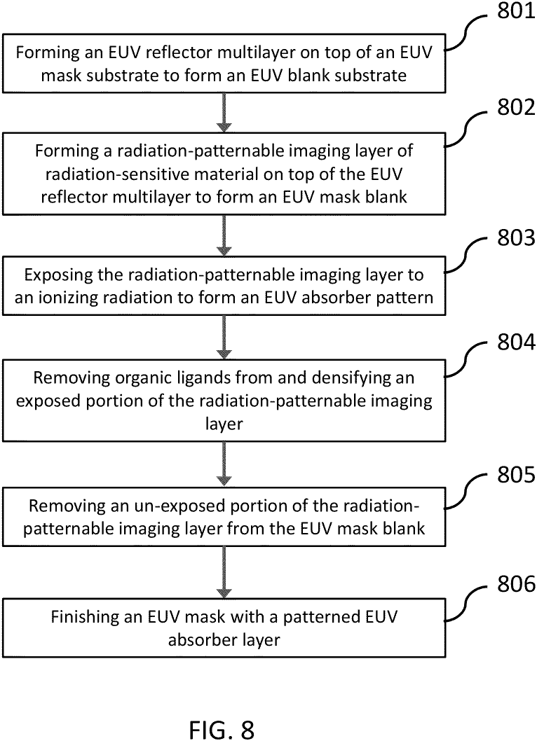

FIG. 8 is a demonstrative illustration of a flow-chart of a method of manufacturing an EUV mask according to embodiments of present invention. More specifically, embodiments of the method include (801) forming an EUV reflector multilayer on top of an EUV mask substrate to form an EUV blank substrate. The EUV reflector multilayer may be a Bragg reflector layer that enhances reflection of the 13.5 nm wavelength radiation in the EUV lithography. Embodiments of the method further include (802) forming a radiation-patternable imaging layer of radiation-sensitive material (RSM) on top of the EUV reflector multilayer to form an EUV mask blank. The RSM layer may be sensitive to ionizing radiation such as electron beam (e-beam) and thus an imaging layer formed therefrom may be patternable through exposure to the radiation. Subsequently, embodiments of the method include (803) exposing the radiation-patternable imaging layer to an ionizing radiation to form an EUV absorber pattern. Embodiments of the method further include (804) causing organic ligands in the portion of exposed radiation-patternable imaging layer to be removed, and in the meantime as well as subsequently densifying the exposed portion of the radiation-patternable imaging layer through, for example, substrate heating. After the densification of the exposed portion of the radiation-patternable imaging layer, embodiments of the method then include (805) removing an un-exposed portion of the radiation-patternable imaging layer. The removal of the un-exposed portion of radiation-patternable imaging layer may be made through, for example, a sublimation process which causes the portions of unexposed radiation-patternable imaging layer to lift from the EUV mask blank through a vapor state, and finally (806) finishing an EUV mask with the patterned absorber layer. The removal of the un-exposed portion of radiation-patternable imaging layer may also be made through a wet development process which causes the portions of unexposed RSM layer to be removed from the EUV mask blank by dissolution in a liquid developer to finish with an EUV mask with the patterned absorber layer.

In the description above, various materials and dimensions for different elements are provided. Unless otherwise noted, such materials are given by way of example only and embodiments are not limited solely to the specific examples given. Similarly, unless otherwise noted, all dimensions are given by way of example and embodiments are not limited solely to the specific dimensions or ranges given.

It is to be understood that the various layers, structures, and/or regions described above are not necessarily drawn to scale. In addition, for ease of explanation one or more layers, structures, and regions of a type commonly used to form semiconductor devices or structures may not be explicitly shown in a given drawing. This does not imply that any layers, structures, and regions not explicitly shown are omitted from the actual semiconductor structures.

Furthermore, it is to be understood that the embodiments discussed herein are not limited to the particular processing steps shown and described herein. In particular, with respect to semiconductor processing steps, it is to be emphasized that the descriptions provided herein are not intended to encompass all of the processing steps that may be used to form a functional semiconductor integrated circuit device. Rather, certain processing steps that are commonly used in forming semiconductor devices, such as, for example, wet cleaning and annealing steps, are purposefully not described herein for economy of description.

Terms such as “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Also, in the figures, the illustrated scale of one layer, structure, and/or region relative to another layer, structure, and/or region is not necessarily intended to represent actual scale.

Semiconductor devices and methods for forming same in accordance with the above-described techniques can be employed in various applications, hardware, and/or electronic systems, including but not limited to personal computers, communication networks, electronic commerce systems, portable communications devices (e.g., cell and smart phones), solid-state media storage devices, functional circuitry, etc. Given the teachings provided herein, one of ordinary skill in the art will be able to contemplate other implementations and applications of embodiments of the invention.

In some embodiments, the above-described techniques are used in connection with manufacture of semiconductor integrated circuit devices that illustratively comprise, by way of non-limiting example, CMOS devices, MOSFET devices, and/or FinFET devices, and/or other types of semiconductor integrated circuit devices that incorporate or otherwise utilize CMOS, MOSFET, and/or FinFET technology.

Accordingly, at least portions of one or more of the semiconductor structures described herein may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While certain features of the invention have been illustrated and described herein, many modifications, substitutions, changes, and equivalents will now occur to those of ordinary skill in the art. Such changes, modification, and/or alternative embodiments may be made without departing from the spirit of present invention and are hereby all considered within the scope of present invention. It is, therefore, to be understood that the appended claims are intended to cover all such modifications and changes as fall within the spirit of the invention.

What is claimed is:

1. An extreme ultraviolet (EUV) mask blank comprising:
an EUV mask substrate;
an EUV reflector multilayer on top of the EUV mask substrate; and
an imaging layer on top of the EUV reflector multilayer,
wherein the imaging layer is a layer of radiation-sensitive material comprising one or more EUV absorbing metallic elements of silver (Ag), platinum (Pt), palladium (Pd), gold (Au), nickel (Ni), and chromium (Cr), and is radiation-patternable.

2. The EUV mask blank of claim 1, wherein the imaging layer comprises one or more organic ligands that are selected from a group that includes acetate, formate, acetylacetonate, azide, carbonate, oxalate, unsaturated hydrocarbons, phosphines, arenes, thiocyanates and bipyridines.

3. The EUV mask blank of claim 1, wherein the imaging layer comprises one or more EUV absorbing chemical compounds of nickel acetate; nickel formate; nickel acetylacetonate; polynuclear nickel complexes, platinum and palladium complexes with azide, carbonate, oxalate and acetylacetonate; polynuclear palladium and platinum complexes, silver and gold complexes with unsaturated hydrocarbons and phosphines; polynuclear silver and gold complexes, chromium complexes with arenes, thiocyanates and bipyridines; and polynuclear chromium complexes with arenes, thiocyanates and bipyridines.

4. The EUV mask blank of claim 1, wherein the layer of radiation-sensitive material is sublimated onto the EUV reflector multilayer to form the imaging layer.

5. The EUV mask blank of claim 1, wherein the imaging layer is patternable through exposure to an ionizing radiation.

6. The EUV mask blank of claim 1, wherein the EUV reflector multilayer comprises multiple transition metal molybdenum (Mo) layers and multiple silicon (Si) layers alternatingly stacked together one over another.

7. The EUV mask blank of claim 1, wherein the EUV mask substrate comprises a low thermal expansion material of fused silica, quartz, or silicon carbide.

8. A radiation-patternable material comprising:
one or more extreme ultraviolet (EUV) absorbing metallic elements; and
organic ligands selected from a group that includes acetate, formate, acetylacetonate, azide, carbonate, oxalate, unsaturated hydrocarbons, phosphines, arenes, thiocyanates and bipyridines,
the radiation-patternable material being adapted for deposition, through a sublimation process, on a surface of an EUV blank substrate to form an ultrathin film.

9. The radiation-patternable material of claim 8, wherein the ultrathin film deposited on the surface of the EUV blank substrate is adapted for removal from the surface of the EUV blank substrate through another sublimation process.

10. The radiation-patternable material of claim 8, wherein the one or more EUV absorbing metallic elements comprise one or more of silver (Ag), platinum (Pt), palladium (Pd), gold (Au), nickel (Ni), and chromium (Cr).

11. The radiation-patternable material of claim 8, comprising one or more EUV absorbing chemical compounds of nickel acetate; nickel formate; nickel acetylacetonate; polynuclear nickel complexes, platinum and palladium complexes with azide, carbonate, oxalate and acetylacetonate; polynuclear palladium and platinum complexes, silver and gold complexes with unsaturated hydrocarbons and phosphines; polynuclear silver and gold complexes, chromium complexes with arenes, thiocyanates and bipyridines; and polynuclear chromium complexes with arenes, thiocyanates and bipyridines.

12. A method of forming an extreme ultraviolet (EUV) mask comprising:
subliming a layer of radiation-sensitive material onto a surface of an EUV blank substrate;
exposing the layer of radiation-sensitive material to an ionizing radiation to form an EUV mask pattern; and
removing a portion of the layer of radiation-sensitive material from the surface of the EUV blank substrate, wherein the portion of the layer of radiation-sensitive material being removed is unexposed to the ionizing radiation.

13. The method of claim 12, wherein removing the portion of the layer of radiation-sensitive material comprises subliming the portion of the layer of radiation-sensitive material off the EUV blank substrate.

14. The method of claim 12, wherein the EUV blank substrate comprises an EUV reflector multilayer formed on top of an EUV mask substrate.

15. The method of claim 12, wherein the radiation-sensitive material comprises one or more EUV absorbing metallic elements of silver (Ag), platinum (Pt), palladium (Pd), gold (Au), nickel (Ni), and chromium (Cr).

16. The method of claim 12, wherein the radiation-sensitive material comprises one or more EUV absorbing chemical compounds of nickel acetate; nickel formate; nickel acetylacetonate; polynuclear nickel complexes, platinum and palladium complexes with azide, carbonate, oxalate and acetylacetonate; polynuclear palladium and platinum complexes, silver and gold complexes with unsaturated hydrocarbons and phosphines; polynuclear silver and gold complexes, chromium complexes with arenes, thiocyanates and bipyridines; and polynuclear chromium complexes with arenes, thiocyanates and bipyridines.

17. The method of claim 12, wherein the radiation-sensitive material comprises organic ligands selected from a group that includes acetate, formate, acetylacetonate, azide, carbonate, oxalate, unsaturated hydrocarbons, phosphines, arenes, thiocyanates and bipyridines.

18. The method of claim 17, wherein exposing the radiation-sensitive material to the ionizing radiation comprises removing the organic ligands from a portion of the radiation-sensitive material that is exposed to the ionizing radiation.

19. The method of claim 18, further comprising densifying the portion of the radiation-sensitive material that is exposed to the ionizing radiation.

20. The method of claim 12, wherein the radiation-sensitive material comprises EUV absorbing metallic elements and organic ligands, further comprising removing the organic ligands from, and densifying, a portion of the radiation-sensitive material that is exposed to the ionizing radiation.
